(19) United States
(12) Patent Application Publication
(10) Pub. No.: US 2018/0272698 A1
(43) Pub. Date: Sep. 27, 2018

(54) INKJET HEAD, INKJET RECORDING APPARATUS, AND DISCHARGING METHOD

(71) Applicant: TOSHIBA TEC KABUSHIKI KAISHA, Tokyo (JP)

(72) Inventor: Hiroyuki Watanabe, Ichikawa Chiba (JP)

(21) Appl. No.: 15/893,338

(22) Filed: Feb. 9, 2018

(30) Foreign Application Priority Data
Mar. 24, 2017 (JP) 2017-058663

(51) Int. Cl. B41J 2/045; B41J 2/16

(52) U.S. Cl. CPC B41J 2/04521; B41J 2/04581; H01L 41/083; B41J 2/1623; B41J 2/1607; B41J 2/04596

(57) ABSTRACT

According to one embodiment, an inkjet head includes a pressure chamber connected to a nozzle, an actuator configured to change a pressure in the pressure chamber, and a controller configured to apply an expansion signal to the actuator for expanding the pressure chamber, apply, subsequent to at least one expansion signal, a contraction signal to the actuator for contracting the pressure chamber, and apply, while the pressure chamber is contracted, an intermediate signal for contracting the pressure chamber by less than the contraction signal contracts the pressure chamber.

### CROSS-REFERENCE TO RELATED APPLICATION

This application is based upon and claims the benefit of priority from Japanese Patent Application No. 2017-058663, filed Mar. 24, 2017, the entire contents of which are incorporated herein by reference.

### FIELD

Embodiments described herein relate generally to an inkjet head, an inkjet recording apparatus, and a discharging method.

### BACKGROUND

An inkjet head of an existing image forming apparatus discharges ink by expansion and contraction of a pressure chamber filled with the ink. Such an inkjet head discharges the ink one drop at a time so as to form an image. That is, the inkjet head typically discharges one drop of ink per discharge operation of one contraction/expansion cycle. In general, the inkjet head is not capable of discharging more than one drop of ink per discharge operation.

### DESCRIPTION OF THE DRAWINGS

FIG. 1 is a block diagram of an inkjet printer according to an embodiment.

FIG. 2 is an enlarged view of an inkjet head.

FIG. 3 is a transverse cross-sectional view of an inkjet head.

FIG. 4 is a longitudinal cross-sectional view of an inkjet head.

FIG. 5 is a block diagram of a head drive circuit.

FIGS. 6A, 6B, 6C, and 6D illustrate states of a pressure chamber.

FIG. 7 is a timing chart of an example waveform applied to an actuator.

### DETAILED DESCRIPTION

In general, according to an embodiment, an inkjet head includes a pressure chamber connected to a nozzle, an actuator configured to change a pressure in the pressure chamber, and a controller configured to apply an expansion signal to the actuator for expanding the pressure chamber, apply, subsequent to at least one expansion signal, a contraction signal to the actuator for contracting the pressure chamber, and apply, while the pressure chamber is contracted, an intermediate signal for contracting the pressure chamber by less than the contraction signal contracts the pressure chamber.

Hereinafter, an inkjet printer (also referred to as an inkjet recording apparatus) according to example embodiments will be described with reference to the accompanying drawings. It should be noted that the particular embodiments explained below are some possible examples of an inkjet recording apparatus according to the present disclosure and do not limit the possible configuration, specifications, or the like of inkjet recording apparatuses according to the present disclosure.

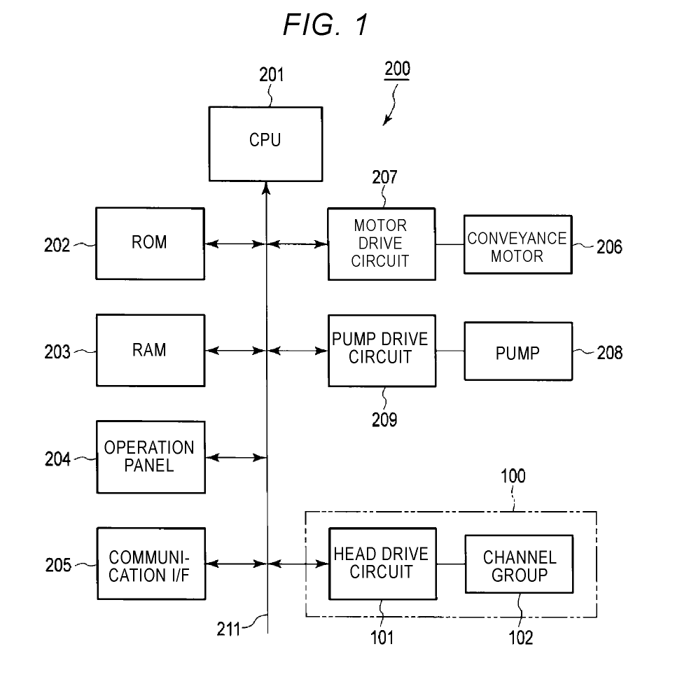

FIG. 1 is a block diagram of an inkjet printer (hereinafter, simply referred to as a printer) 200. The printer 200 is applied to, for example, an office printer, a barcode printer, a POS printer, an industrial printer, etc.

The printer 200 includes a central processing unit (CPU) 201, a read only memory (ROM) 202, a random access memory (RAM) 203, an operation panel 204, a communication interface 205, a conveyance motor 206, a motor drive circuit 207, a pump 208, a pump drive circuit 209, and an inkjet head 100. The printer 200 includes a bus line 211 such as an address bus, a data bus, or the like. In the printer 200, each of the CPU 201, the ROM 202, the RAM 203, the operation panel 204, the communication interface 205, the motor drive circuit 207, the pump drive circuit 209, and a head drive circuit 101 of the inkjet head 100 is connected to the bus line 211 directly or through an input/output circuit.

The CPU 201 corresponds to a central unit of a computer. The CPU 201 controls respective units so as to implement various functions of the printer 200 according to an operating system or an application program.

The ROM 202 corresponds to a main memory unit of the computer. The ROM 202 stores the operating system or the application program as described above. The ROM 202 may store data required when the CPU 201 executes processing for controlling the respective units.

The RAM 203 corresponds to a main memory unit of the computer. The RAM 203 stores data necessary for the CPU 201 to execute processing. The RAM 203 is also used as a work area in which information is properly rewritten by the CPU 201. The work area includes an image memory in which print data is developed.

The operation panel 204 includes an operation unit and a display. On the operation unit, functional keys such as a power key, a paper feed key, and an error release key are disposed. The display can display various states of the printer 200.

The communication interface 205 receives print data from a client terminal connected through a network such as a local area network (LAN). The communication interface 205 sends an error notification signal to the client terminal, for example, when an error occurs in the printer 200.

The motor drive circuit 207 drives the conveyance motor 206. The conveyance motor 206 functions as a driving source of a conveyance mechanism that conveys recording medium such as printing paper. When the conveyance motor 206 is driven, the conveyance mechanism conveys the recording medium. The conveyance mechanism conveys the recording medium to a printing position of the inkjet head 100. The conveyance mechanism discharges the recording medium on which printing has been completed, from a discharge port (not illustrated) to the outside of the printer 200.

The pump drive circuit 209 drives the pump 208. When the pump 208 is driven, the ink within an ink tank (not illustrated) is supplied to the inkjet head 100.

The head drive circuit 101 drives a channel group 102 of the inkjet head 100 based on print data.

Hereinafter, inkjet heads according to example embodiments will be described with reference to the accompanying drawings. In the example embodiments described below, it is assumed that a share mode-type inkjet head 100 discharges the ink to paper. It should be noted, that the particular embodiments explained below are some possible examples of an inkjet head and printing media according to the present disclosure and do not limit the scope of the present disclosure and other inkjet head types.

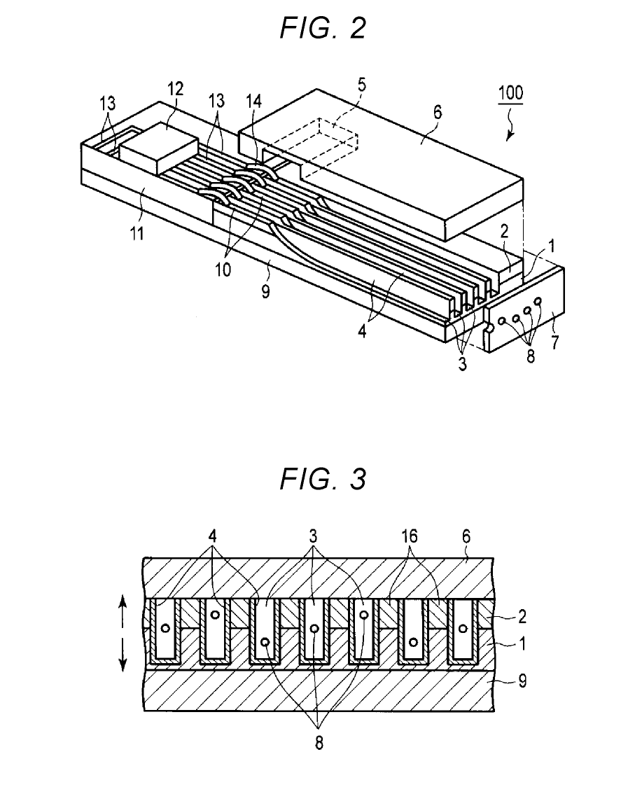

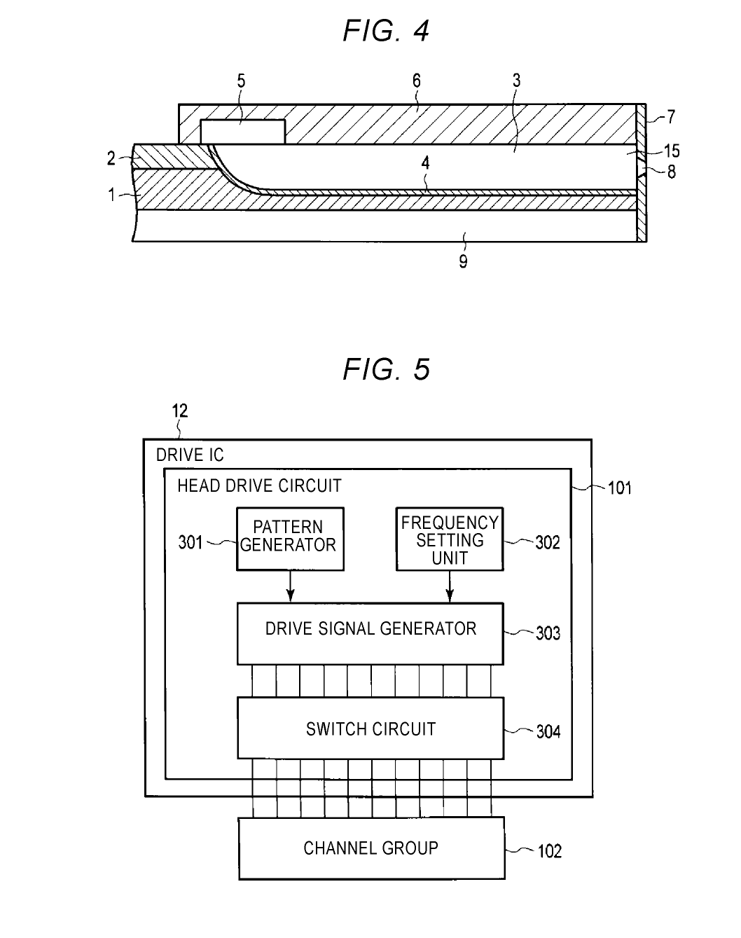

Thereafter, the inkjet head 100 will be described with reference to FIGS. 2 to 4. FIG. 2 is an enlarged perspective view of the inkjet head 100. FIG. 3 is a transverse cross-sectional view of the inkjet head 100. FIG. 4 is a longitudinal cross-sectional view of the inkjet head 100.

As illustrated in FIG. 2, the inkjet head 100 includes a base substrate 9. In the inkjet head 100, a first piezoelectric plate 1 is bonded to an upper surface of the base substrate 9, and a second piezoelectric plate 2 is bonded onto the first piezoelectric plate 1. The first piezoelectric plate 1 and the second piezoelectric plate 2, which are bonded to each other, have polarizations in opposite directions along a direction parallel to the thickness of the piezoelectric plates 1 and 2 as indicated by the arrows of FIG. 3.

The base substrate 9 is made of a material that has a small dielectric constant, and a small difference of a thermal expansion coefficient from the first piezoelectric plate 1 and the second piezoelectric plate 2. Examples of materials that can be used to form the base substrate 9 include alumina (Al₂O₃), silicon nitride (Si₃N₄), silicon carbide (SiC), aluminum nitride (AlN), and lead zirconate titanate (PZT. Examples of materials that can be used to form the first piezoelectric plate 1 and the second piezoelectric plate 2 include lead zirconate titanate (PZT), lithium niobate (LiNbO₃), and lithium tantalate (LiTaO₃).

The inkjet head 100 includes multiple elongated grooves 3 cut from an upper surface of the first piezoelectric plate 1 towards a bottom surface of the second piezoelectric plate 2. The grooves 3 are equally spaced and parallel to one another. Each groove 3 has an open upper end and closed bottom end.

As illustrated in FIGS. 3 and 4, the inkjet head 100 has an electrode 4 on inner walls and a bottom surface of each groove 3. The electrode 4 has a two-layered structure of nickel (Ni) and gold (Au). The electrode 4 is uniformly formed as a film inside each groove 3 by, for example, a plating method. A method of forming the electrode 4 is not limited to a plating method. For example, a sputtering method or a deposition method can be used.

As illustrated in FIG. 2, the inkjet head 100 includes a lead-out electrode 10 at a rear edge of each groove 3 toward a rear upper surface of the second piezoelectric plate 2. The lead-out electrode 10 is connected to the electrode 4.

As illustrated in FIGS. 2 and 4, the inkjet head 100 includes a top plate 6 and an orifice plate 7. The top plate 6 covers the upper ends of the grooves 3. In the orifice plate 7 covers the front edges of grooves 3. In the inkjet head 100, each of a plurality of pressure chambers 15 is formed by in one groove 3 shielded by the top plate 6 and the orifice plate 7. The pressure chamber 15 has, for example, a depth of 300 μm and a width of 80 μm. The pressure chambers 15 are arranged in parallel with one another at a pitch of 169 μm. Each of the pressure chamber 15 may interchangeably be referred to as an ink chamber.

The top plate 6 includes a common ink chamber 5 at a rear bottom surface of the top plate 6. The orifice plate 7 includes nozzles 8 facing respective grooves 3. The nozzles 8 communicate with the respective grooves 3, that is, the pressure chambers 15. Each of the nozzles 8 is tapered from the pressure chamber 15 toward an ink discharge side, which is opposite of the pressure chamber 15. The nozzles 8 corresponding to three adjacent pressure chambers 15 are grouped, and within each group heights of the three nozzles are shifted at a constant interval in the height direction of the grooves 3 (in the vertical direction of the paper surface in FIG. 3).

As illustrated in FIG. 3, in the piezoelectric plates 1 and 2 partition walls are formed on both sides of each of the plurality of pressure chambers 15outside the electrodes 4. The partition walls form an actuator 16.

As illustrated in FIG. 2, in the inkjet head 100, a printed circuit board 11 having conductive patterns 13 is bonded to a rear upper surface of the base substrate 9. In the inkjet head 100, a drive integrated circuit (IC) 12 having the head drive circuit 101 (also referred to as a controller) is mounted on the printed circuit board 11. The drive IC 12 is connected to the conductive patterns 13. The conductive pattern 13 is connected with each lead-out electrode 10 by a conducting wire 14 through wire bonding.

Hereinafter, a combination of one pressure chamber 15 in one groove 3, the electrode 4 inside the groove 3, and the nozzle 8 facing the groove 3 will be referred to as a channel. That is, the inkjet head 100 having N grooves 3 includes N channels ch.1, and ch.N.

FIG. 5 is a block diagram of the head drive circuit 101. The head drive circuit 101 is disposed within the drive IC 12.

The head drive circuit 101 drives a channel group (ch.1 through ch.N) 102 of the inkjet head 100 based on print data.

The channel group 102 includes multiple channels. As described above, each channel is a combination of one pressure chambers 15 in one groove 3, the electrode 4 inside the groove 3, the nozzle 8 facing the groove 3. That is, the channel group 102 discharges an ink when each pressure chamber 15 is expanded and contracted by the actuator 16, driven by a control signal from the head drive circuit 101.

As illustrated in FIG. 5, the head drive circuit 101 includes a pattern generator 301, a frequency setting unit 302, a drive signal generator 303, a switch circuit 304, and the like.

The pattern generator 301 generates various waveform patterns including an expansion pulse signal (also referred to as an expansion signal) that expands the volume of the pressure chamber 15, a pause signal that restores the volume of the pressure chamber 15, a contraction pulse signal (also referred to as a contraction signal) that contracts the volume of the pressure chamber 15, and an intermediate potential pulse signal (also referred to an intermediate signal) having a half of the voltage of the contraction pulse signal.

The frequency setting unit 302 sets a frequency of a driving pulse (also referred to as a driving frequency) generated by the drive signal generator 303 according to print data input from the bus line. The head drive circuit 101 operates according to the driving pulse.

The drive signal generator 303 generates pulse signals for each channel based on the waveform patterns generated by the pattern generator 301 and the driving frequency set by the frequency setting unit 302. The pulse signals for each channel are output from the drive signal generator 303 to the switch circuit 304.

The switch circuit 304 switches a voltage applied to the electrode 4 of each channel according to the pulse signals for each channel which are output from the drive signal generator 303. That is, the switch circuit 304 applies a voltage to the actuator 16 of each channel based on an energization time or the like of the expansion pulse signal specified in the pattern generator 301.

The switch circuit 304 causes the volume of the pressure chamber 15 of each channel to switch between expanding and contracting through switching of the voltage, such that the nozzle 8 of each channel discharges ink droplets according to intended pattern gradations.

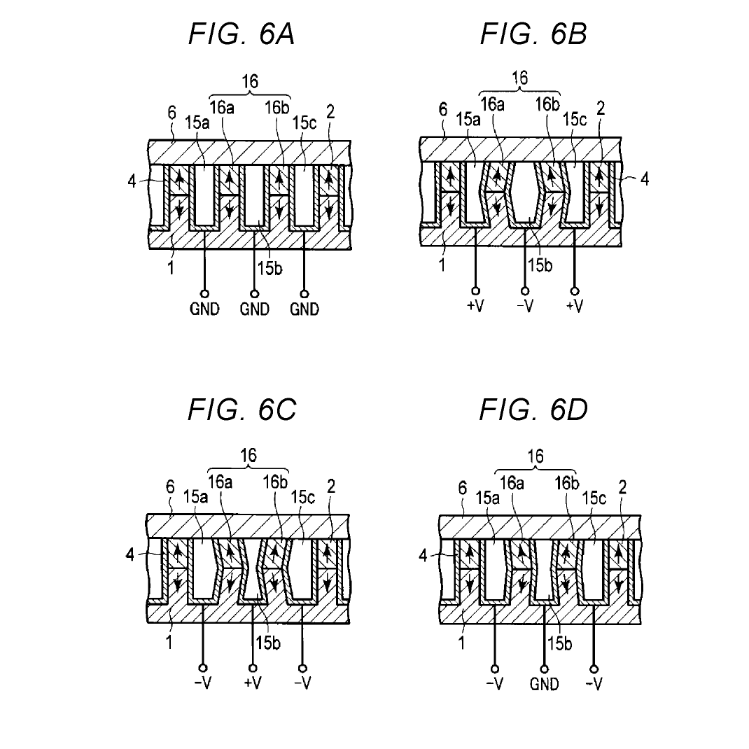

Thereafter, the operation aspects of the inkjet head 100 configured as described above will be described with reference to FIGS. 6A to 6D.

FIG. 6A illustrates a state of a pressure chamber 15b during a pause signal. During the pause signal, the pressure chamber 15b is in a neutral state without being expanded or contracted. As illustrated in FIG. 6A, the head drive circuit 101 sets potentials of the electrodes 4 on wall surfaces of the pressure chamber 15b, and pressure chambers 15a and 15c adjacent to the pressure chamber 15b at both sides of the pressure chamber 15b, to ground potentials GND. In this state, both a partition wall 16a, between the pressure chambers 15a and 15b, and a partition wall 16b, between the pressure chambers 15b and 15c, do not distort.

FIG. 6B illustrates a state in which the head drive circuit 101 applies an expansion pulse signal to the actuator 16 of the pressure chamber 15b.

The expansion pulse signal is formed in a rectangular pulse shape with a predetermined width. The expansion pulse signal expands the pressure chamber 15b. As illustrated in FIG. 6B, the head drive circuit 101 applies a negative voltage −V to the electrode 4 of the pressure chamber 15b and applies a positive voltage +V to the electrodes 4 of the pressure chambers 15a and 15c at the sides of the pressure chamber 15b. In this state, an electric field caused by a voltage twice the voltage V acts on each of the partition walls 16a and 16b in a direction orthogonal to the polarization direction of the first piezoelectric plate 1 and the second piezoelectric plate 2. Thus, each of the partition walls 16a and 16b is deformed outwards so as to expand the pressure chamber 15b.

FIG. 6C illustrates a state in which the head drive circuit 101 applies a contraction pulse signal to the actuator 16 of the pressure chamber 15b.

The contraction pulse signal is formed in a rectangular shape with a predetermined width. The contraction pulse signal contracts the pressure chamber 15b. As illustrated in FIG. 6C, the head drive circuit 101 applies a positive voltage +V to the electrode 4 of the pressure chamber 15b, and applies a negative voltage −V to the electrodes 4 of the pressure chambers 15a and 15c at both sides of the pressure chamber 15b. In this state, an electric field caused by a voltage twice the voltage V acts on each of the partition walls 16a and 16b in a direction opposite to the direction in the state of FIG. 6B. Thus, each of the partition walls 16a and 16b is deformed inwards so as to contract the volume of the pressure chamber 15b.

FIG. 6D illustrates a state in which the head drive circuit 101 applies an intermediate potential pulse signal to the actuator 16 of the pressure chamber 15b.

The intermediate potential pulse signal is formed in a rectangular shape with a predetermined width. The intermediate potential pulse signal contracts the pressure chamber 15. The intermediate potential pulse signal contracts the pressure chamber 15 weakly as compared to the contraction pulse signal. That is, the intermediate potential pulse signal contracts the pressure chamber 15 by a volume less than the volume contracted by the contraction pulse signal.

As illustrated in FIG. 6D, the head drive circuit 101 sets the electrode 4 of the pressure chamber 15b to a ground potential GND, and applies a negative voltage −V to the electrodes 4 of the pressure chambers 15a and 15c at both sides of the pressure chamber 15b. In this state, an electric field caused by a voltage V acts on each of the partition walls 16a and 16b in the same direction as the direction in the state of FIG. 6C. Thus, each of the partition walls 16a and 16b is deformed inwards so as to contract the volume of the pressure chamber 15b. As illustrated in FIG. 6D, the partition walls 16a and 16b are deformed less inwards from the state illustrated in FIG. 6C.

The head drive circuit 101 may apply a positive electrode voltage V to the electrode 4 of the pressure chamber 15b as an intermediate potential pulse signal while the electrodes 4 of the pressure chambers 15a and 15c at both sides of the pressure chamber 15b are set to a ground potential GND.

In this manner, the partition walls 16a and 16b which separate the pressure chambers 15a, 15b, and 15c serve as the actuator 16 that causes a pressure variation inside the pressure chamber 15b. That is, the pressure chamber 15 is contracted and expanded by the operation of the actuator 16.

Each pressure chamber 15 shares the actuator 16 with an adjacent pressure chamber 15. The actuator 16 serves as a partition wall between adjacent pressure chambers 15. Thus, the head drive circuit 101 cannot individually drive all of the pressure chambers 15. The head drive circuit 101 drives a group of the pressure chambers 15 at a time. One group includes (n+1) of the pressure chambers 15 at intervals of n pressure chambers (n is an integer of 2 or more). In the present example embodiment, the head drive circuit 101 drives a set of three pressure chambers 15 at intervals of two chambers. This example is referred to as a three-division driving. However, a four-division driving, a five-division driving or the like may also be used.

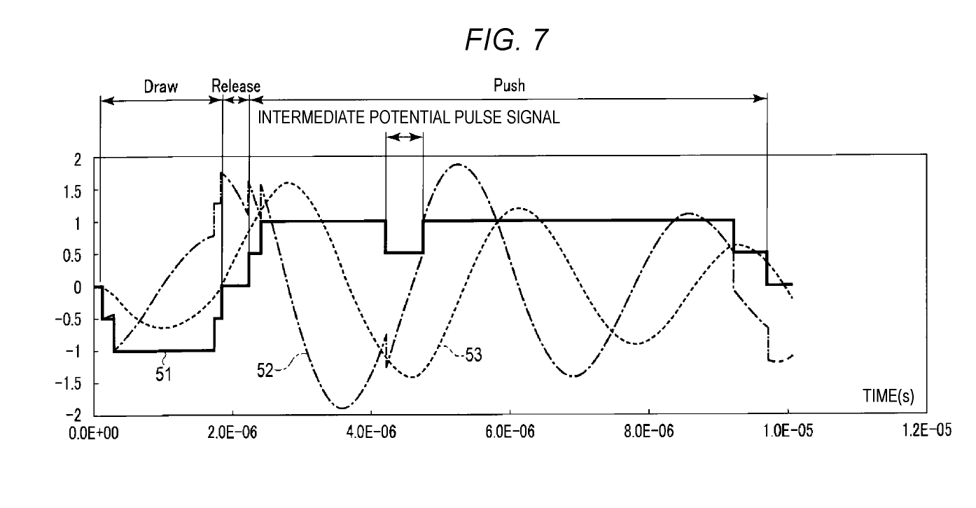

FIG. 7 is a timing chart of an example waveform applied to the actuator 16 of the pressure chamber 15 by the head drive circuit 101. FIG. 7 illustrates a drive voltage applied to the actuator 16, a pressure variation in the pressure chamber 15, and a velocity of a meniscus surface on the nozzle 8. Here, the horizontal axis indicates a time from a start of the waveform.

The graph 51 indicates a drive voltage applied to the actuator 16. The vertical axis indicates a voltage. In the vertical axis, a voltage that drives the actuator 16 in a direction in which the pressure chamber 15 expands is set as a negative voltage, and a voltage that drives the actuator 16 in a direction in which the pressure chamber 15 is contracted is set as a positive voltage.

The graph 52 indicates a pressure within the pressure chamber 15. The vertical axis indicates a magnitude of the pressure.

The graph 53 indicates a velocity of a meniscus surface formed on the nozzle 8 communicating with the pressure chamber 15. The vertical axis indicates the magnitude of the velocity of the meniscus surface.

The head drive circuit 101 applies a discharge pulse signal to the actuator 16 that causes ink to be discharged. As illustrated in FIG. 7, the discharge pulse signal is composed of a “Draw” period, a “Release” period, and a “Push” period in this order. It is assumed that when the pressure within the pressure chamber 15 exceeds a predetermined threshold value (a discharge threshold value), the ink will be discharged from the pressure chamber 15.

The “Draw” period is a period during which the pressure chamber 15 expands to fill the pressure chamber 15 with ink. In the “Draw” period, the head drive circuit 101 applies an expansion pulse signal to the actuator 16. For example, the head drive circuit 101 applies the expansion pulse signal with a width of about 1.6 μs to the actuator 16.

The head drive circuit 101 may expand the pressure chamber 15 gradually in the “Draw” period. For example, the head drive circuit 101 may apply a half of the voltage of the expansion pulse signal for a predetermined period of time and then apply the full expansion pulse signal voltage. After applying the expansion pulse signal, the head drive circuit 101 may apply a half of the voltage of the expansion pulse signal and then end the Draw period.

When the “Draw” period ends, the head drive circuit 101 proceeds to the “Release” period.

The “Release” period is a period during which the pressure chamber 15 is returned to a state where the pressure chamber 15 is not expanded or contracted. The head drive circuit 101 applies a pause signal for the “Release” period. For example, the head drive circuit 101 sets the “Release” period to be about 0.2 μs.

When the “Release” period ends, the head drive circuit 101 proceeds to the Push period.

The “Push” period is a period during which the pressure chamber 15 is contracted. In the “Push” period, the head drive circuit 101 applies a contraction pulse signal to the actuator 16. For example, the “Push” period is about five to seven times the “Draw” period.

At a predetermined timing after the head drive circuit 101 applies the contraction pulse signal to the actuator 16, the pressure in the pressure chamber 15 exceeds the discharge threshold value. As a result, the ink is discharged from the nozzle 8.

The head drive circuit 101 applies an intermediate potential pulse signal to the actuator 16 at a predetermined timing during the “Push” period. That is, after applying the contraction pulse signal with a predetermined width to the actuator 16, the head drive circuit 101 applies the intermediate potential pulse signal with a predetermined width to the actuator 16. After the intermediate potential pulse signal with the predetermined width is applied, the head drive circuit 101 applies the contraction pulse signal to the actuator 16 again.

When the intermediate potential pulse signal is applied while the pressure chamber 15 is contracted, the pressure chamber 15 expands and approaches the released state. When the head drive circuit 101 applies the contraction pulse signal after applying the intermediate potential pulse signal, the pressure chamber 15 is contracted again. That is, the head drive circuit 101 may contract the pressure chamber 15 again by applying the intermediate potential pulse signal while also applying the contraction pulse signal by which the pressure chamber 15 is further contracted.

For example, the width of the intermediate potential pulse signal ranges from about 1.7 μs to 1.8 μs.

The head drive circuit 101 applies the intermediate potential pulse signal to the actuator 16 such that the pressure of the pressure chamber 15 can increase after the intermediate potential pulse signal is applied. For example, the head drive circuit 101 terminates the intermediate potential pulse signal when the pressure in the pressure chamber 15 is at a minimum pressure after ink is discharged and increases again. That is, while the pressure of the pressure chamber 15 increases from the minimum pressure, the head drive circuit 101 switches from the intermediate potential pulse signal to the contraction pulse signal.

As a result, while the pressure in the pressure chamber 15 increases from the minimum pressure, the pressure chamber 15 is contracted again and the pressure in the pressure chamber 15 further increases. Therefore, the pressure in the pressure chamber 15 exceeds the discharge threshold value, and the ink is discharged from the nozzle 8.

After the ink is discharged, the pressure within the pressure chamber 15 decreases and then increases again. As a result of another rise in the pressure, the pressure in the pressure chamber 15 can exceed the discharge threshold value again, and the ink will be discharged from the nozzle 8 again.

Accordingly, the head drive circuit 101 may discharge the ink three times during one discharge pulse signal in this manner.

In the “Push period”, the head drive circuit 101 may contract the pressure chamber 15 gradually. For example, the head drive circuit 101 may apply the intermediate potential pulse signal with a predetermined width and then apply the contraction pulse signal. After applying the contraction pulse signal, the head drive circuit 101 may apply the intermediate potential pulse signal with a predetermined width and then terminate the Push period.

The head drive circuit 101 may continuously apply the discharge pulse signal to the actuator 16.

In the “Push” period, the head drive circuit 101 may apply the intermediate potential pulse signal multiple times to the actuator 16.

The head drive circuit 101 may apply the intermediate potential pulse signal to the actuator 16 according to a timing of a second pressure rise after the ink is discharged.

The head drive circuit 101 may cause the ink to dispense twice from the pressure chamber 15. The head drive circuit 101 may cause the ink to dispense four or more times from the pressure chamber 15.

The voltage of the intermediate potential pulse signal need not be one half of the voltage of the contraction pulse signal. In general, the voltage of the intermediate potential pulse signal is not limited to any specific value as long as the voltage value does not contract the pressure chamber beyond that caused by the contraction pulse signal.

In the example embodiment described herein, the inkjet head applies the discharge pulse signal composed of the “Draw” period, the “Release” period, and the “Push” period to the actuator 16. In the “Push” period, the inkjet head applies the intermediate potential pulse signal to the actuator 16 so as to contract the pressure chamber again. Therefore, the pressure in the pressure chamber rises again, and the inkjet head may discharge the ink.

As a result, the inkjet head may discharge the ink multiple times with one discharge pulse signal.

The inkjet head may reduce the power required per drop.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. An inkjet head, comprising:
a pressure chamber connected to a nozzle;
an actuator configured to change a pressure in the pressure chamber; and
a controller configured to:
apply an expansion signal to the actuator for expanding the pressure chamber,
apply, subsequent to at least one expansion signal, a contraction signal to the actuator for contracting the pressure chamber, and
apply, while the pressure chamber is contracted, an intermediate signal for contracting the pressure chamber by less than the contraction signal contracts the pressure chamber.

2. The inkjet head according to claim 1, wherein the controller switches between applying the intermediate signal and the contraction signal to the actuator.

3. The inkjet head according to claim 2, wherein the contraction signal increases a pressure in the pressure chamber sufficiently to eject an ink droplet from the nozzle and then the intermediate signal attenuates the pressure in the pressure chamber after the ink droplet is ejected.

4. The inkjet head according to claim 3, wherein, when the pressure in the pressure chamber is increasing, the controller switches from applying the intermediate signal to the actuator to applying the contraction signal to the actuator.

5. The inkjet head according to claim 4, wherein the contraction signal is applied to the actuator to increase the pressure in the pressure chamber to eject another ink droplet after at least one intermediate signal has been applied to the actuator.

6. The inkjet head according to claim 2, wherein the controller sets frequencies of the contraction signal and the intermediate signal according to external print data input.

7. The inkjet head according to claim 1, wherein
the contraction signal is a rectangular shaped pulse having a first voltage, and
the intermediate signal is a rectangular shaped pulse and having a second voltage, the second voltage is being one half of the first voltage.

8. An inkjet recording apparatus, comprising:
a conveyance motor configured to convey recording medium;
a pressure chamber connected to a nozzle through which ink can be discharged onto the recording medium;
an actuator configured to change a pressure in the pressure chamber; and
a controller configured to:
apply an expansion signal to the actuator for expanding the pressure chamber,
apply, subsequent to at least one expansion signal, a contraction signal to the actuator for contracting the pressure chamber, and
apply, while the pressure chamber is contracted, an intermediate signal for contracting the pressure chamber by less than the contraction signal contracts the pressure chamber.

9. The inkjet recording apparatus according to claim 8, wherein the controller switches between applying the intermediate signal and the contraction signal to the actuator.

10. The inkjet recording apparatus according to claim 9, wherein the contraction signal increases a pressure in the pressure chamber sufficiently to eject an ink droplet from the nozzle and then the intermediate signal attenuates the pressure in the pressure chamber after the ink droplet is ejected.

11. The inkjet recording apparatus according to claim 10, wherein, when the pressure in the pressure chamber is increasing, the controller switches from applying the intermediate signal to the actuator to applying the contraction signal to the actuator.

12. The inkjet recording apparatus according to claim 11, wherein the contraction signal is applied to the actuator to increase the pressure in the pressure chamber to eject another ink droplet after at least one intermediate signal has been applied to the actuator.

13. The inkjet recording apparatus according to claim 9, wherein the controller sets frequencies of the contraction signal and the intermediate signal according to external print data input.

14. The inkjet recording apparatus according to claim 8, wherein the contraction signal is a rectangular shaped pulse having a first voltage, and
the intermediate signal is a rectangular shaped pulse and having a second voltage, the second voltage is being one half of the first voltage.

15. A method of discharging ink, the method comprising:
applying an expansion signal to an actuator for expanding a pressure chamber connected to a nozzle;
applying, subsequent to at least one expansion signal, a contraction signal to the actuator for contracting the pressure chamber; and
applying, while the pressure chamber is contracted, an intermediate signal for contracting the pressure chamber by less than the contraction signal contracts the pressure chamber.

16. The method of discharging ink according to claim 15, wherein the contraction signal increases a pressure in the pressure chamber sufficiently to eject an ink droplet from the nozzle and then the intermediate signal attenuates the pressure in the pressure chamber after the ink droplet is ejected.

17. The method of discharging ink according to claim 16, further comprising:
when the pressure in the pressure chamber is increasing, switching from applying the intermediate signal to the actuator to applying the contraction signal to the actuator.

18. The inkjet recording apparatus according to claim 17, further comprising:
applying the contraction signal to the actuator to increase the pressure in the pressure chamber to eject another ink droplet after at least one intermediate signal has been applied to the actuator.

19. The inkjet recording apparatus according to claim 15, further comprising:
setting frequencies of the contraction signal and the intermediate signal according to external print data input.

20. The inkjet recording apparatus according to claim 15, wherein
the contraction signal is a rectangular shaped pulse having a first voltage, and
the intermediate signal is a rectangular shaped pulse and having a second voltage, the second voltage is being one half of the first voltage.
